(19) United States
(12) Patent Application Publication
(10) Pub. No.: US 2014/0375346 A1
(43) Pub. Date: Dec. 25, 2014

(54) TEST CONTROL DEVICE AND METHOD FOR TESTING SIGNAL INTEGRITIES OF ELECTRONIC PRODUCT

(71) Applicant: FIH (Hong Kong) Limited, Kowloon (HK)

(72) Inventor: MING-SHIU OU YANG, New Taipei (TW)

(21) Appl. No.: 14/314,301

(22) Filed: Jun. 25, 2014

(30) Foreign Application Priority Data
Jun. 25, 2013 (TW) 102122509

(51) Int. Cl. G01R 31/28

(52) U.S. Cl. CPC G01R 31/2806; G01R 31/2803
USPC 324/754.03

(57) ABSTRACT

A test control device and a method automatically test signal integrities of an electronic product. The test control device includes an oscilloscope and robot devices each holding a probe of the oscilloscope. The test control device sets test projects and locations of test points of each test project on the electronic product. The test control device selects a test project and selects probes for measuring electrical outputs at the test points of the selected test project, controls robot devices holding the selected probes to move tips of the selected probes to touch the test points, and controls the electronic product to activate the test points. The oscilloscope measures the electrical outputs at the test points through the selected probes. The test control device further obtains results of the measurements from the oscilloscope, analyzes and integrates all of the measurements, and generates a signal integrity report of the electronic product.

### CROSS-REFERENCE TO RELATED APPLICATIONS

This application claims priority to Taiwanese Patent Application No. 102122509 filed on Jun. 25, 2013 in the China Intellectual Property Office, the contents of which are incorporated by reference herein.

### FIELD

The subject matter herein generally relates to signal testing technologies, and particularly to a test control device and a method for automatically testing signal integrities of an electronic product.

### BACKGROUND

Signals output from test points on an electronic product, such as a printed circuit board (PCB), are measured to ensure that electrical characteristics of the electronic product meet technical standards and requirements.

### BRIEF DESCRIPTION OF THE DRAWINGS

Implementations of the present disclosure will now be described, by way of example only, with reference to the attached figures, wherein:

FIG. 1 illustrates diagrammatic illustration of one embodiment of a test control device that automatically tests signal integrities of an electronic product.

FIG. 2 is a block diagram of the test control device of FIG. 1.

FIG. 3 is a flowchart illustrating a method for automatically testing signal integrities of an electronic product.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

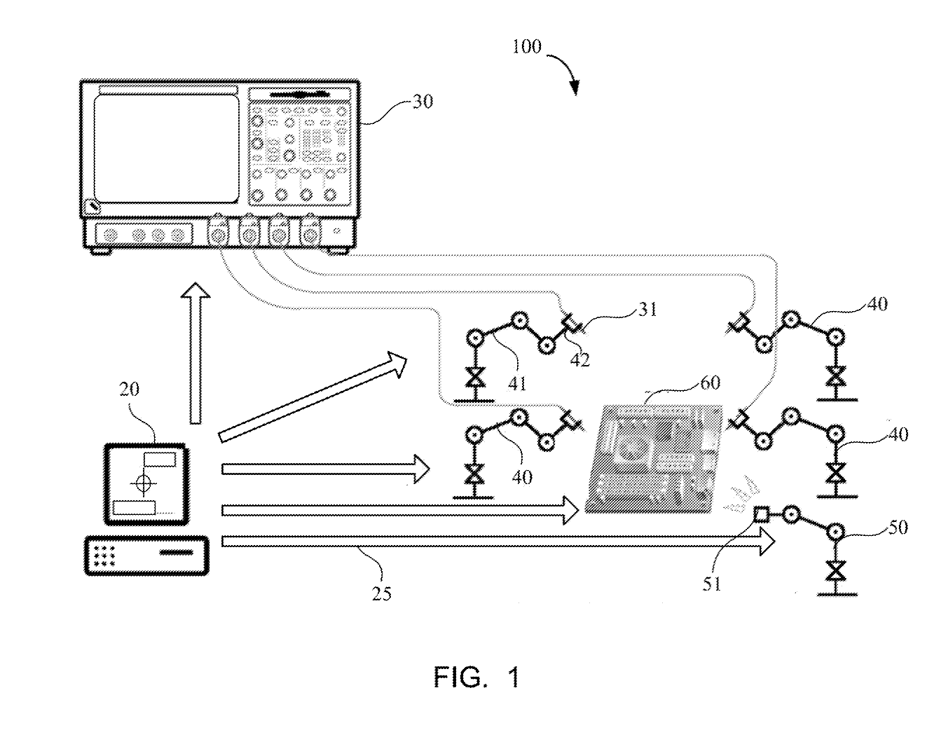

FIG. 1 illustrates one embodiment of a test control device 20 controlling test apparatuses 100 to automatically test signal integrity of test points of an electronic product 60. In the embodiment, the test apparatuses 100 include an oscilloscope 30 and a number of robot devices 40 each holding a probe 31 of the oscilloscope 30. In one embodiment, each robot device 40 includes a robot arm 41 and a holder 42. The holder 42 can firmly hold a probe 31, and the robot arm 41 can move the holder 42.

The test control device 20 is coupled to the oscilloscope 30, the robot devices 40, and the electronic product 60 through signal wires 25. In one embodiment, the test control device 20 can be a host computer. The electronic product 60 can be a printed circuit board (PCB) equipped with a plurality of electronic components, such as resistors, capacitors, inductors, and integrated circuit (IC) chips. The test points on the electronic product 60 can include a VCC point and grounding (GND) point of each electronic component. The probes 31 can detect the electrical outputs at the test points on the electronic product 60 when the probes 31 touch the test points, and the oscilloscope 30 can measure the values of the electrical outputs through the probes 31.

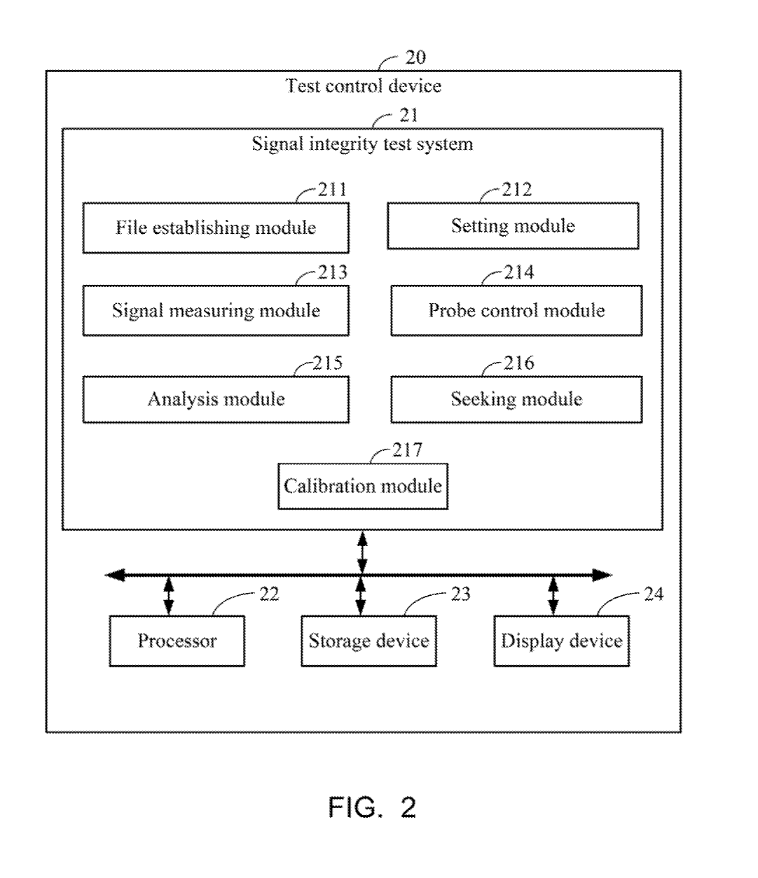

FIG. 2 is a block diagram of the test control device 20. In the embodiment, a signal integrity test system 21 is installed in the test control device 20 that controls the test apparatuses 100 to automatically test signal integrity of the electronic product 60. In the embodiment, the test control device 20 further includes at least one processor 22, a storage device 23, and a display device 24. The processor 22 controls the test control device 20 to govern the signal integrity test system 21. The storage device 23 stores data, such as a file of a test plan, or a signal integrity report.

As shown in FIG. 2, the signal integrity test system 21 includes a file establishing module 211, a setting module 212, a signal measuring module 213, a probe control module 214, and an analysis module 215, all of which are in a collection of software and executed by the at least one processor 22.

In one embodiment, the file establishing module 211 can create a file of a test plan including a table in response to tester's operation of creating a file. The test plan file can be a spreadsheet document, such as an EXCEL document, or a text document, such as a WORD document, and can be stored in the storage device 23.

The setting module 212 can set test projects and parameters of each test project in the table in response to tester's inputs. In one embodiment, the parameters of each test project include locations of test points on the electronic product 60, and allocating names of electrical outputs at the test points. In one embodiment, the setting module 212 can further set starting locations of tips of the probes 31 and relationships of the probes 31 and the robot devices 40 in the table.

The signal measuring module 213 can select a test project from the table and select probes 31 for measuring electrical outputs at the test points of the selected test project.

The probe control module 214 can control the robot devices 40 holding the selected probes 31 to move the tips of the selected probes 31 to touch the test points of the selected test project. In one embodiment, the probe control module 214 can calculate displacements of the selected probes 31 from the starting locations to the locations of test points, and generate movement commands including the displacements, to control the associated robot devices 40 to drive the robot arm 41 to move, in order to move the tip of the fixed probes 31 to touch the test points.

In one embodiment, the test apparatuses 100 further includes a seeking device 50. The signal integrity test system 21 further includes a seeking module 216, which can control the seeking device 50 to seek and determine actual locations of the tips of the selected probes 31 after the selected probes 31 are driven to move. In one embodiment, the probe control module 214 can further control the associated robot devices 40 to adjust the locations of the tips of the selected probes 31 according to the required locations of the test points of the selected test project and the actual locations of the tips of the selected probes 31.

The signal measuring module 213 can further output commands to control the electronic product 60 which is being tested to be electrically active at the test points, and control the oscilloscope 30 to measure the electrical outputs at the test points through the selected probes 31.

The setting module 212 can further obtain results of the measurements from the oscilloscope 30, and record the result of the measurements in the table.

The analysis module 215 can analyze and integrate the results of the measurements of all test projects, and generate a signal integrity report of the electronic product 60. The signal integrity report can be stored in the storage device 23 and displayed on the display device 24 for the tester to evaluate the performance of the electronic product 60.

In one embodiment, the probe control module 214 can further control the associated robot devices 40 to move the tips of the selected probes 31 back to the starting locations after the selected test project is finished.

In one embodiment, the signal integrity test system 21 further includes a calibration module 217, which can calibrate the oscilloscope 30 and each of the robot devices 40 before a test.

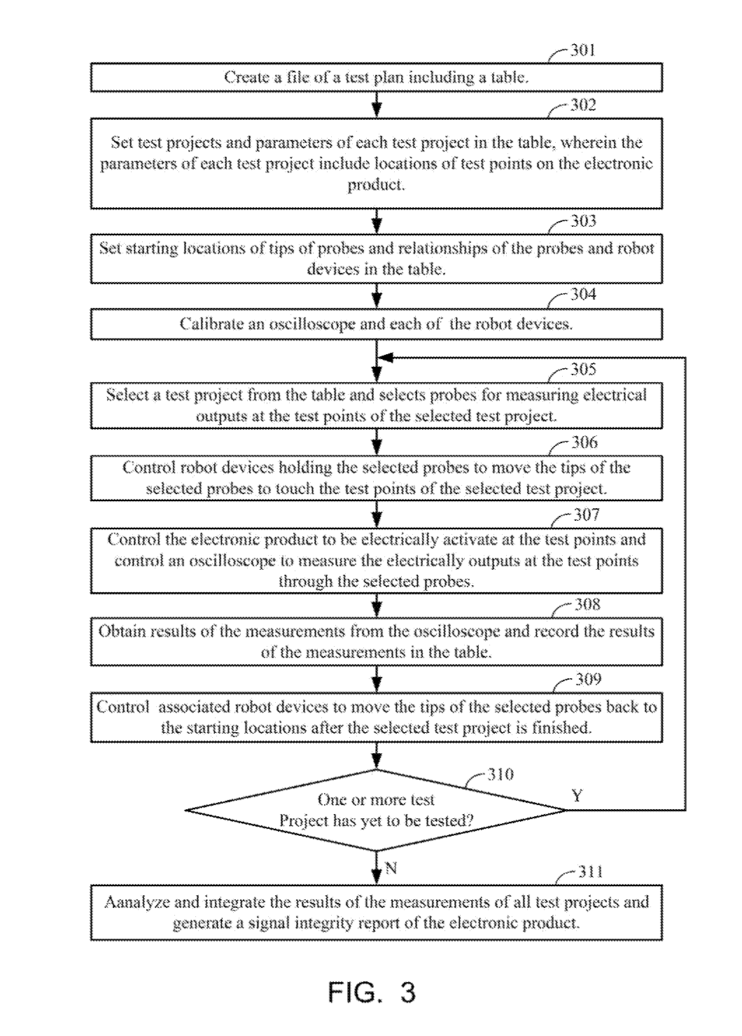

Referring to FIG. 3, a flowchart is presented in accordance with an example embodiment. The example method 300 is provided by way of example, as there are a variety of ways to carry out the method. The method 300 described below can be carried out using the configurations illustrated in FIGS. 1 and 2, for example, and various elements of these figures are referenced in explaining example method 300. Each block shown in FIG. 3 represents one or more processes, methods, or subroutines, carried out in the example method 300. Furthermore, the illustrated order of blocks is illustrative only and the order of the blocks can change. Additional blocks can be added or fewer blocks may be utilized, without departing from this disclosure. The example method 300 can begin at block 301.

At block 301, a file establishing module creates a file of a test plan including a table in response to tester's operation of creating a file. The test plan file can be a spreadsheet document, such as an EXCEL document, or a text document, such as a WORD document, and can be stored in a storage device.

At block 302, a setting module sets test projects and parameters of each test project in the table in response to tester's inputs. In one embodiment, the parameters of each test project include locations of test points on an electronic product, and allocating names of electrical outputs at test points.

At block 303, the setting module further sets starting locations of tips of probes and relationships of the probes and robot devices in the table.

At block 304, a calibration module calibrates an oscilloscope and each of the robot devices.

At block 305, a signal measuring module selects a test project from the table and selects probes for measuring electrical outputs at the test points of the selected test project.

At block 306, a probe control module controls the robot devices holding the selected probes to move the tips of the selected probes to touch the test points of the selected test project.

In one embodiment, the probe control module calculates displacements of the selected probes 31 from the starting locations to the locations of test points, and generates movement commands including the displacements to control the robot devices to move the tips of the probes to touch the test points.

In one embodiment, a seeking module controls a seeking device to seek and determine actual locations of the tips of the selected probes after the selected probes are driven to move. The probe control module further controls the associated robot devices to adjust the locations of the tips of the selected probes according to the required locations of the test points of the selected test project and the actual locations of the tips of the selected probes.

At block 307, the signal measuring module further outputs commands to control the electronic product which is being tested to be electrically activate at the test points, and controls an oscilloscope to measure the electrical outputs at the test points through the selected probes.

At block 308, the setting module further obtains results of the measurements from the oscilloscope and records the result of the measurements in the table.

At block 309, the probe control module further controls the robot devices to move the tips of the selected probes back to the starting locations after the selected test project is finished.

At block 310, the signal measuring module determines whether one or more test project set in the table have yet to be tested. If the signal measuring module determines that one or more test project have yet to be tested, the procedure returns to block 305. If the signal measuring module determines that every test project has been tested, the procedure goes to block 311.

At block 311, an analysis module analyzes and integrates the results of the measurements of all test projects, and generates a signal integrity report of the electronic product. The signal integrity report can be stored in the storage device and displayed on a display device for the tester to evaluate the performance of the electronic product.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size, and arrangement of parts within the principles of the present disclosure, up to and including the full extent established by the broad general meaning of the terms used in the claims.

What is claimed is:

1. A test control device for controlling test apparatuses to automatically test signal integrities of an electronic product, wherein the test apparatuses comprise an oscilloscope and robot devices each holding a probe of the oscilloscope, the test control device comprising:
at least one processor; and
a plurality of modules to be executed by the at least one processor, the modules comprising:
a file establishing module configured to create a file of a test plan comprising a table in response to tester's operation of creating a file;
a setting module configured to set test projects and parameters of each test project in the table in response to tester's inputs, wherein the parameters of each test project comprise locations of test points on the electronic product;
a signal measuring module configured to select a test project from the table and select probes for measuring electrical outputs at the test points of the selected test project;
a probe control module configured to control the robot devices holding the selected probes to move the tips of the selected probes to touch the test points of the selected test project;
the signal measuring module further configured to output commands to control the electronic product which is being tested to be electrically active at the test points and control the oscilloscope to measure the electrical outputs at the test points through the selected probes;
the setting module further configured to obtain results of the measurements from the oscilloscope and record the results of the measurements in the table; and
an analysis module configured to analyze and integrate the results of the measurements of all test projects and generate a signal integrity report of the electronic product.

2. The test control device as described in claim 1, wherein the setting module further configured to set starting locations of tips of the probes and relationships of the probes and the robot devices in the table; and
the probe control module controls the robot devices holding the selected probes to move the selected probes to touch the test points of the selected test project by:
calculating displacements of the selected probes from the starting locations to the locations of test points, and generating movement commands comprising the displacements, to control the associated robot devices to move the fixed probe to touch the test points.

3. The test control device as described in claim 1, further comprising a seeking module configured to control a seeking device to seek and determine actual locations of the tips of the selected probes after the selected probes are driven to move; and
the probe control module further configured to control the associated robot devices to adjust the locations of the tips of the selected probes according to the required locations of the test points of the selected test project and the actual locations of the tips of the selected probes.

4. The test control device as described in claim 1, further comprising a calibration module configured to calibrate the oscilloscope and each of the robot devices before a test.

5. The test control device as described in claim 1, wherein the probe control module is further configured to control the associated robot devices to move the tips of the selected probes back to the starting locations after the selected test project is finished.

6. A method for controlling test apparatuses to automatically test signal integrities of an electronic product, wherein the test apparatuses comprise an oscilloscope and robot devices each holding a probe of the oscilloscope, the method comprising:
creating a file of a test plan file comprising a table in response to tester's operation of creating a file;
setting test projects and parameters of each test project in the table in response to tester's inputs, wherein the parameters of each test project comprise locations of test points on the electronic product;
selecting a test project from the table and select probes for measuring electrical outputs at the test points of the selected test project;
controlling robot devices holding the selected probes to move tips of the selected probes to touch the test points of the selected test project;
controlling the electronic product which is being tested to be electrically active at the test points and controlling the oscilloscope to measure the electrical outputs at the test points through the selected probes;
obtaining results of the measurements from the oscilloscope and recording the results of the measurements in the table; and
analyzing and integrating the results of the measurements of all test projects and generating a signal integrity report of the electronic product.

7. The method as described in claim 6, further comprising:
setting starting locations of tips of the probes and relationships of the probes and the robot devices in the table.

8. The method as described in claim 7, wherein controlling the robot devices associated to the selected probes to move the selected probes to touch the test points of the selected test project comprising:
calculating displacements of the selected probes from the starting locations to the locations of test points; and
generating movement commands comprising the displacements to control the associated robot devices to move the fixed probe to touch the test points.

9. The method as described in claim 8, further comprising:
controlling a seeking device to seek and determine actual locations of the tips of the selected probes after the selected probes are driven to move; and
controlling the associated robot devices to adjust the locations of the tips of the selected probes according to the required locations of the test points of the selected test project and the actual locations of the tips of the selected probes.

10. The method as described in claim 6, further comprising:
calibrating the oscilloscope and each of the robot devices.

11. The method as described in claim 6, further comprising:
controlling the associated robot devices to move the tips of the selected probes back to the starting locations after the selected test project is finished.
